(19) United States
(12) Patent Application Publication
(10) Pub. No.: US 2025/0029875 A1
(43) Pub. Date: Jan. 23, 2025

(54) PACKING STRUCTURE AND METHOD FOR FORMING THE SAME

(71) Applicant: Winbond Electronics Corp., Taichung City (TW)

(72) Inventors: Yen-Jui CHU, Taichung City (TW); Yu-Jen LIN, Taichung City (TW); Min-Hsun LIN, Tainan City (TW); Chung-Ming CHENG, Tainan City (TW)

(21) Appl. No.: 18/620,054

(22) Filed: Mar. 28, 2024

(30) Foreign Application Priority Data
Jul. 17, 2023 (TW) 112126536

(51) Int. Cl. H01L 21/768; H01L 23/00; H01L 23/498; H01L 25/065

(52) U.S. Cl. CPC H01L 21/76883; H01L 23/49838; H01L 24/32; H01L 24/83; H01L 25/0657; H01L 2224/32145; H01L 2224/83896; H01L 2924/15

(57) ABSTRACT

A method for forming a packaging structure is provided. The method includes providing a first substrate and a second substrate. The first substrate includes a first base material and a first dielectric layer on the first base material, and the second substrate includes a second base material and a second dielectric layer on the second base material. The second base material has a first through hole. The first dielectric layer and the second dielectric layer have a first hole and a second hole, respectively. The method further includes connecting the second substrate to the first substrate in such a way that the second dielectric layer is connected to the first dielectric layer to form a first composite structure; thinning the top surface of the first composite structure to expose the first through hole; and forming a first conductive member in the first through hole.

### CROSS REFERENCE TO RELATED APPLICATIONS

This application claims priority of Taiwan Patent Application No. 112126536, filed on Jul. 17, 2023, the entirety of which is incorporated by reference herein.

### BACKGROUND OF THE INVENTION

### Field of the Invention

The present invention relates to a packaging structure, and, in particular, to a method of forming conductive members.

### Description of the Related Art

Through-silicon vias (TSV) and wire bonding are widely used in the packaging process. Through-silicon vias and wire bonding demand the application of many semiconductor processing technologies (such as photolithography process, etching, deposition process, planarization process, etc.) and back-end technologies (such as thinning process, bumping process, wire bonding process, etc.). In a wire bonding process, when the die is bonded to solder bumps, there is likely to be residual glue, which can affect electrical conduction. Alternatively, when the die is bonded by hybrid wire bonding, a difference between the center and the edge of the wafer is likely to occur, resulting in air gaps or dish-shaped recesses. Also, problems such as a waste of materials and increased machining costs may arise. Therefore, the industry still needs to improve the packaging structure and the method for forming the same to overcome the above-mentioned problems.

### BRIEF SUMMARY OF THE INVENTION

Embodiments of the present disclosure provide a method for forming a packaging structure. The method includes providing a first substrate and a second substrate. The first substrate includes a first base material and a first dielectric layer on the first base material, and the second substrate includes a second base material and a second dielectric layer on the second base material. The second base material has a first through hole. The first dielectric layer and the second dielectric layer have a first hole and a second hole, respectively. The method further includes connecting the second substrate to the first substrate in such a way that the second dielectric layer directly contacts the first dielectric layer to form a first composite structure; thinning the top surface of the first composite structure to expose the first through hole; and forming a first conductive member in the first through hole.

Embodiments of the present disclosure provide a packaging structure. The structure includes a first substrate, a second substrate, a third substrate, a conductive member and a conductive line. The first substrate includes a first base material and a first dielectric layer thereon, the second substrate includes a second base material and a second dielectric layer thereon, and the third substrate includes a third base material and a third dielectric layer thereon. The conductive member is surrounded by the first dielectric layer, the second dielectric layer, the second base material, the third dielectric layer, and the third base material and is in direct contact with them. The conductive member penetrates the third base material and is exposed. The conductive line is surrounded by the third dielectric layer. The conductive line is spaced apart from the third base material by the third dielectric layer.

### BRIEF DESCRIPTION OF THE DRAWINGS

The present invention can be more fully understood by reading the subsequent detailed description and examples with references made to the accompanying drawings, wherein:

FIG. 1 shows a cross-sectional view illustrating the formation of a packaging structure at a stage according to some embodiments of the present disclosure.

FIG. 2A shows a cross-sectional view illustrating the second dielectric layer of the packaging structure according to some embodiments of the present disclosure.

FIG. 2B shows a top view illustrating the second dielectric layers of the packaging structure according to some embodiments of the present disclosure.

FIGS. 3-9 show cross-sectional views illustrating the formation of a packaging structure at different stages according to some embodiments of the present disclosure.

FIGS. 10-11 show cross-sectional views illustrating the formation of a packaging structure at different stages according to other embodiments of the present disclosure.

### DETAILED DESCRIPTION OF THE INVENTION

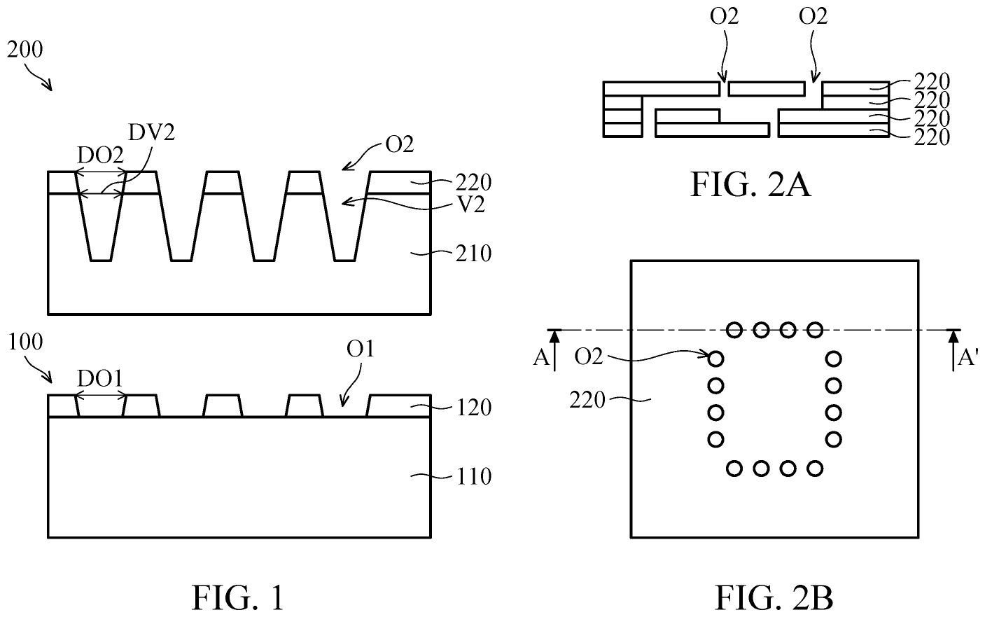

FIGS. 1, 3-9 show cross-sectional views illustrating the formation of a packaging structure at different stages according to some embodiments of the present disclosure. FIG. 2A shows a cross-sectional view illustrating the dielectric layer 220 of the packaging structure according to some embodiments of the present disclosure. FIG. 2B shows a top view illustrating the dielectric layers 220 of the packaging structure according to some embodiments of the present disclosure.

Referring to FIGS. 1, 2A and 2B, a substrate 100 and a substrate 200 are provided. In an embodiment, the substrate 100 includes a base material 110 and a dielectric layer 120 formed thereon, and the substrate 200 includes a base material 210 and a dielectric layer 220 formed thereon.

In an embodiment, the substrate 110 and the substrate 210 may both be dies, which may include various elements (not shown), such as active elements, passive elements, interconnect structures, or combinations thereof. For example, active elements include transistors and diodes. Passive elements include, for example, capacitors, inductors, and resistors. Interconnect structures may include multiple layers of metal lines and through holes formed in a dielectric structure. Multiple layers of metal lines and through holes are electrically connected to various components to form a functional circuit.

In an embodiment, the base material 210 may have a through hole V2. The through hole V2 may be formed, for example, by an etching process. The etching process may be an anisotropic etching process, which includes various dry etching processes, such as reactive ion etching, neutral particle beam etching, inductively coupled plasma etching, or combinations thereof. The through hole V2 may extend from a surface of the base material 210 into the base material 210. In an embodiment, the through hole V2 may have a maximum width DV2 (at the top surface of the base material 210) in a cross-sectional view.

In an embodiment, the dielectric layer 120 and the dielectric layer 220 may include inorganic dielectric materials and/or organic dielectric materials. The dielectric layer 120 and the dielectric layer 220 may be, for example, polymer films, which include polyimide (PI), polybenzoxazole (PBO), benzocyclobutene (BCB), or the like, or combinations thereof. In an embodiment, the dielectric layer 120 and the dielectric layer 220 may be a single layer or a plurality of layers. For example, in the embodiment shown in FIG. 1, the dielectric layer 120 and the dielectric layer 220 are both shown as a single layer, while in the embodiment shown in FIG. 2A, the dielectric layer 220 has a plurality of layers stacked on top of each other, and have holes O2.

In an embodiment, the dielectric layer 120 and the dielectric layer 220 may respectively have holes O1 and holes O2. For example, the holes O1 and the holes O2 may be formed, for example, by a mechanical drilling process. The holes O1 may extend from a surface of the dielectric layer 120 through the dielectric layer 120 to the other surface. The holes O2 may extend from one surface of the dielectric layer 220 through the dielectric layer 220 to the other surface. The holes O1 and the holes O2 may be via holes. In an embodiment, in a sectional-view, the holes O1 may have a maximum width DO1 (at the top surface of the dielectric layer 120), and the holes O2 may have a maximum width DO2 (at the top surface of the dielectric layer 220). It should be noted that the dielectric layer 220 in FIGS. 1, 3-9 is a cross-sectional view along the line A-A′ in FIG. 2B.

The width DO1 of the holes O1, the width DO2 of the holes O2, and the width DV2 of the through hole V2 are not particularly limited, and may be adjusted according to actual needs. However, if the width DO2 was substantially equal to the width DO1, as the conductive ink will be filled later, it may avoid the conductive ink filling in the corners and thereby avoid increasing the material cost.

In an embodiment, the dielectric layer 120 may be adhered to the base material 110 through an adhesive layer (not shown), and the dielectric layer 220 may be adhered to the base material 210. In an embodiment, the dielectric layer 220 is adhered on the base material 210 by aligning the hole O2 of the dielectric layer 220 to the through hole V2 of the base material 210. The adhesive layer may be an adhesive, which may include materials similar to the dielectric layer 120 or the dielectric layer 220, such as polymers that may include polyimide, polyurethane, epoxy resin, and the like.

It can be seen from FIG. 1 that the hole O1 exposes the base material 110, and the hole O2 exposes the base material 210.

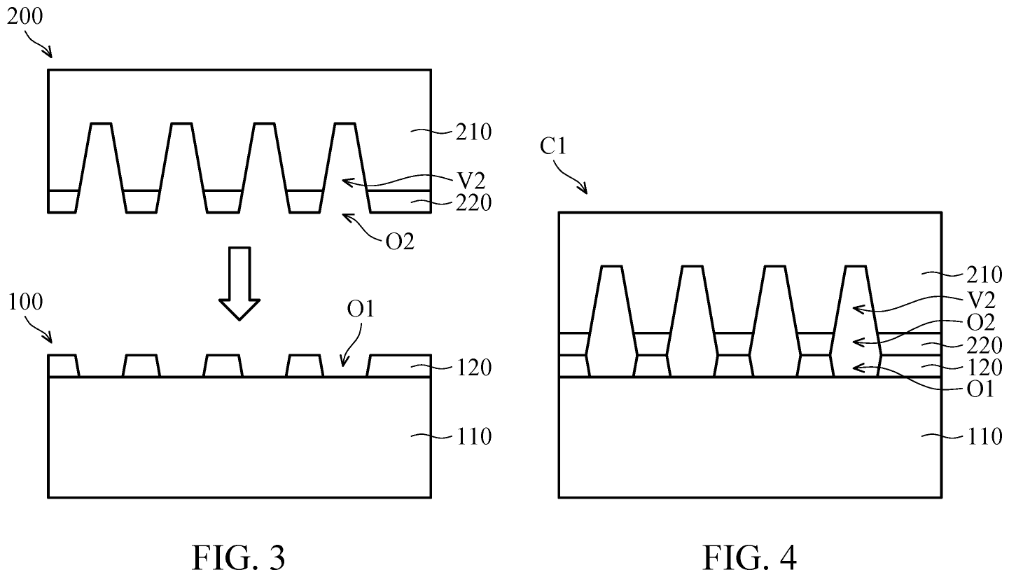

Next, referring to FIGS. 3-4, the substrate 200 is connected to the substrate 100 in such a way that the dielectric layer 220 directly contacts the dielectric layer 120 to form a first composite structure C1. In detail, the hole O2 of the dielectric layer 220 is aligned with the hole O1 of the dielectric layer 120 to form a first composite structure C1.

In an embodiment, the formation of the first composite structure C1 includes coating an adhesive layer (not shown) onto the dielectric layer 120; and adhering the dielectric layer 220 to the dielectric layer 120 using the adhesive layer. The material of the adhesive layer is similar to the above and will not be repeated here.

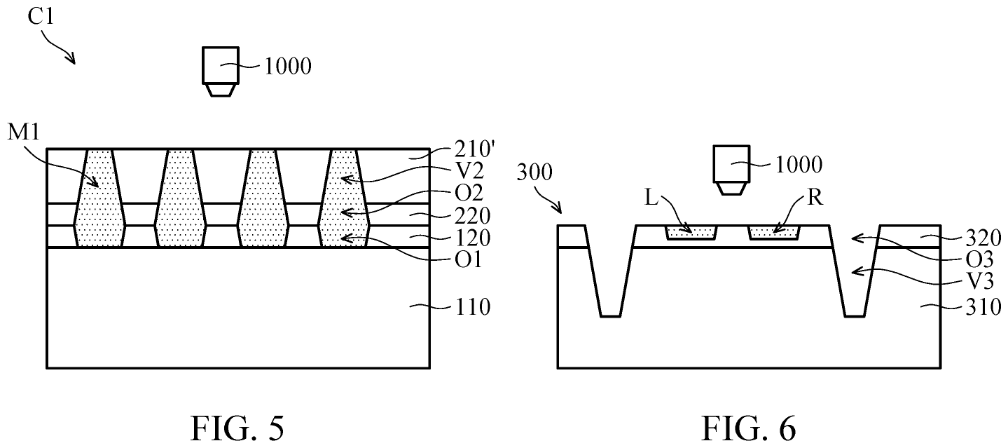

Next, referring to FIG. 5, the top surface of the first composite structure C1 is thinned to expose the through hole V2. Also, a conductive member M1 is formed in the through hole V2. In an embodiment, the conductive member M1 directly contacts the substrate 200.

In an embodiment, thinning the top surface of the first composite structure C1 includes removing excess portions of the first composite structure C1 through a planarization process (such as chemical mechanical polishing) or an etching process in order to expose the through hole V2.

In an embodiment, the conductive member M1 is formed by a printing process 1000. The printing process 1000 may include a screen printing process, a jet printing process, a 3D printing process, and the like. In an embodiment, the printing process 1000 includes filling a conductive ink into the through hole V2 and curing the conductive ink in the through hole V2. The conductive ink includes metallic ink, such as nano-silver ink, nano-copper-silver alloy ink, nano-gold ink, and the like. Curing includes applying heat or light to the conductive ink. The heating process is, for example, a low-temperature sintering process at a temperature below 250° C. (for example, 120° C. to 220° C., and 160° C. to 200° C.). The light process is, for example, using laser light or ultraviolet light or the like.

Compared with the comparative example of depositing conductive material first and then thinning in the prior art, in the embodiment of the present disclosure, the conductive member is formed by printing process after thinning. Thereby, the incomplete deposition (such as gaps) in the prior art may be reduces and also the deposition of copper seed layers (and thus the aspect ratio of through hole is reduced) may be avoided. Therefore, not only the complexity of the process is reduced, but also the reliability of the structure is improved.

Next, referring to FIG. 6, a substrate 300 is provided. The substrate 300 includes a base material 310 and a dielectric layer 320 thereon. The base material 310 has a through hole V3, and the dielectric layer 320 has a hole O3. In an embodiment, the dielectric layer 320 further includes a recess R (used as a conductive line L after a printing process). In the case that the recess R is designed not to be connected to an external circuit, the conductive line L may be formed first in this step by the printing process 1000. The printing process 1000 is similar to the above and will not be repeated here. The material of the remaining portion of the substrate 300 (for example, is a die) is similar to the substrate 200. That is, the material of the base material 310 is similar to the base material 210. The formation of the through hole V3 is similar to that of the through hole V2. The material and formation of the dielectric layer 320 are similar to that of the dielectric layer 220. The formation of the hole O3 is similar to that of the hole O2, which will not be repeated here.

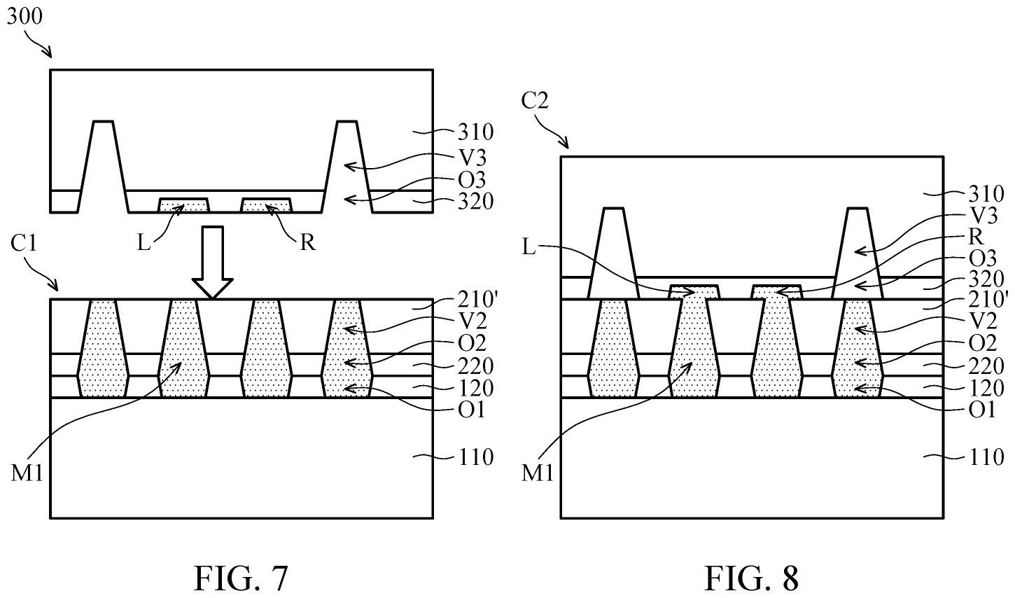

Next, referring to FIGS. 7-8, the substrate 300 is connected to the first composite structure C1 to form a second composite structure C2. In detail, the dielectric layer 320 of the substrate 300 is connected to the top surface of the first composite structure C1 where the through hole V2 is exposed. More specifically, the second composite structure C2 is formed by aligning the hole O3 and the recess R of the dielectric layer 320 to the through hole V2 of the first composite structure C1.

In an embodiment, the formation of the second composite structure C1 includes coating an adhesive layer (not shown) onto the dielectric layer 320; and adhering the dielectric layer 320 to the first composite structure C1 using the adhesive layer. The material of the adhesive layer is similar to the above and will not be repeated here.

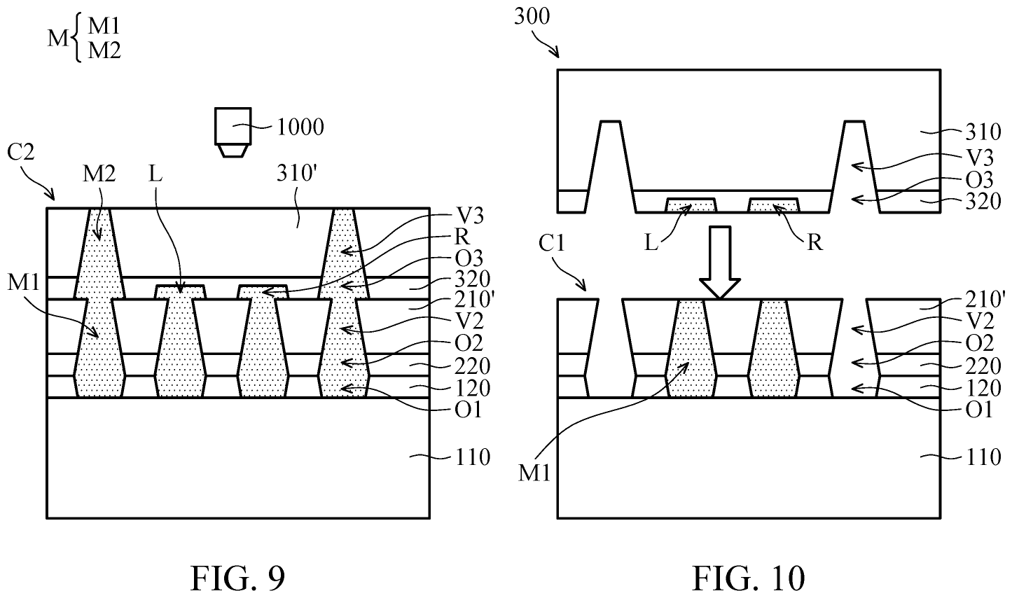

Next, referring to FIG. 9, the top surface of the second composite structure C2 is thinned to expose the through hole V3. Also, a conductive member M2 is formed in the through hole V3. In an embodiment, the conductive member M2 directly contacts the substrate 300.

In an embodiment, thinning the top surface of the second composite structure C2 includes removing an excess portion of the second composite structure C2 through a planarization process or an etching process in order to expose the through hole V3. In an embodiment, the conductive member M2 is formed by the printing process 1000, which is similar to the above, and will not be repeated here.

It can be seen from FIG. 9 that the conductive member M1 and the conductive member M2 (or collectively referred to as the conductive member M) are connected or conductive line L and the conductive member M1 are connected. Because they are formed by filling and curing the conductive ink, so no air gap generated therein. In addition, the conductive member M1, the conductive member M2, and the conductive line L may be regarded as integrally formed.

As shown in FIG. 9, the conductive member M directly contacts and is surrounded by the dielectric layer 120, the dielectric layer 220, the base material 210′, the dielectric layer 320, and the base material 310′. The conductive member M penetrates through the base material 310′ and is exposed. The conductive line L is surrounded by the dielectric layer 320. The conductive line L is spaced apart from the base material 310′ by the dielectric layer 320. It should be noted that, on the structure shown in FIG. 9, more base materials and/or dielectric layers may be continuously formed through processes similar to the above according to actual needs.

Based on the above, the embodiments of the present disclosure may directly bond a plurality of dies through a plurality of dielectric layers and a plurality of base materials, thereby avoiding the steps of forming bumps and bonding wires. Also, the unevenness of the metal interface or the different sizes of the wire bonding bumps may be avoided. Therefore, the problems of generating air gaps or residual glue when bonding dies may be avoided. Moreover, the complicated deposition steps in the traditional manufacturing process may be reduced by the printing process, and the waste of materials may be reduced, thereby reducing the cost.

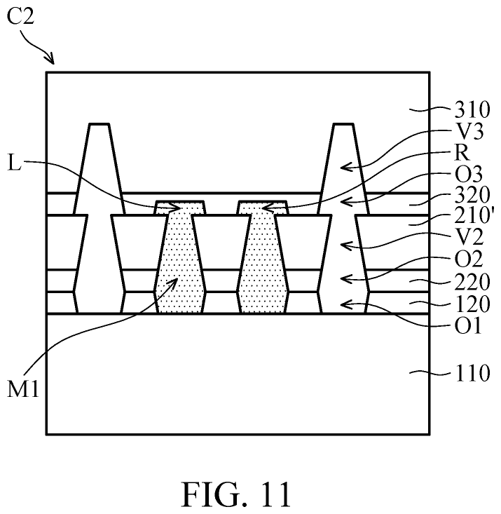

FIGS. 10-11 show cross-sectional views illustrating the formation of a packaging structure at different stages according to other embodiments of the present disclosure.

FIG. 10 is a continuation of FIG. 6. The difference between FIG. 10 and FIG. 7 is that the conductive member M1 is not formed first in the through hole V2 aligned with the through hole V3. That is, as shown in FIG. 6, the conductive member M1 is formed in the through hole V2 aligned with the conductive line L not connected to the external circuit, and the conductive member M1 is not formed in the through hole V3 connected to the external circuit.

Next, referring to FIG. 11, which is similar to FIG. 8, the substrate 300 is connected to the first composite structure C1 to form a second composite structure C2. Next, similar to the above, the top surface of the second composite structure C2 is thinned to expose the through hole V3. Furthermore, the conductive member M1 and the conductive member M2 are formed in the via holes V2 and V3 at the same time through the printing process 1000, and the result is the same as that shown in FIG. 9.

As mentioned above, the through holes connected to external circuits may be printed after the die bonding is completed to form conductive members therein in order to further reduce process steps and costs.

To sum up, the embodiments of the present disclosure may integrally form the redistribution layer, the conductive lines in the die, and the through holes in the packaging structure through the printing process, thereby improving the bonding force and electrical properties. In an embodiment, by using a plurality of dielectric layers with holes, multiple layers of redistribution layers may be designed arbitrarily, which increases the flexibility of the conductive line design. In an embodiment, by using a printing process to form the conductive members, additional barrier layers (such as Ta/Ti, etc.), copper seed layers (Cu seed layers) and copper seed layers (Cu seed layers) added when the conductive members are formed by the deposition process in the conventional process may be avoided. Therefore, a large aspect ratio may be maintained and the generation of air gaps may be reduced. In an embodiment, by stacking a plurality of base materials and a plurality of dielectric layers without using a bumping process and a wire bonding process, a redistribution layer between dies may be directly formed and contact dies to reduce the overall height and simplify the process steps and complexity. In an embodiment, the through holes in each base material are penetrated through a thinning process, and the conductive members are formed by a printing process at the end, which can reduce multiple and complicated deposition processes.

Although the present invention is disclosed above with the foregoing embodiments, it is not intended to limit the present invention. Those with ordinary knowledge in the technical field of the present invention may make some changes and modifications without departing from the spirit and scope of the present invention. Therefore, the scope of protection of the present invention should be defined by the scope of the appended patent application.

What is claimed is:

1. A method, comprising:
providing a first substrate and a second substrate,
wherein the first substrate includes a first base material and a first dielectric layer on the first base material, and the second substrate includes a second base material and a second dielectric layer on the second base material,
wherein the second base material has a first through hole, and the first dielectric layer and the second dielectric layer have a first hole and a second hole, respectively;
connecting the second substrate to the first substrate in such a way that the second dielectric layer is connected to the first dielectric layer to form a first composite structure;
thinning a top surface of the first composite structure to expose the first through hole; and
forming a first conductive member in the first through hole.

2. The method as claimed in claim 1, wherein forming the first conductive member comprises:
using a printing process.

3. The method as claimed in claim 2, wherein using the printing process comprises:
filling a conductive ink into the first through hole; and
curing the conductive ink in the first through hole.

4. The method as claimed in claim 1, wherein providing the second substrate comprises:
forming the second dielectric layer on the second base material, wherein the second hole of the second dielectric layer is aligned with the first through hole of the second base material.

5. The method as claimed in claim 1, wherein the first hole exposes the first base material, and the second hole exposes the second base material.

6. The method as claimed in claim 1, wherein the first conductive member directly contacts the second substrate.

7. The method as claimed in claim 1, wherein connecting the second substrate to the first substrate comprises:
the second hole of the second dielectric layer being aligned with the first hole of the first dielectric layer.

8. The method as claimed in claim 7, wherein forming the first conductive member further comprises:
forming the first conductive member in the first hole and the second hole.

9. The method as claimed in claim 1, wherein neither wiring nor bumps are formed after forming the first conductive member.

10. The method as claimed in claim 1, further comprising:
providing a third substrate, which comprises a third base material and a third dielectric layer on the third base material, wherein the third base material has a second through hole, wherein the third dielectric layer has a third hole;
connecting the third substrate to the first composite structure to form a second composite structure;
thinning a top surface of the second composite structure to expose the second through hole; and
forming a second conductive member in the second through hole.

11. The method as claimed in claim 10, wherein the first conductive member and the second conductive member are formed integrally.

12. The method as claimed in claim 10, wherein connecting the third substrate to the first composite structure comprises:
the third dielectric layer of the third substrate being connected to a top surface of the second through hole exposed by the first composite structure.

13. The method as claimed in claim 10, wherein after thinning the top surface of the second composite structure, the first conductive member and the second conductive member are formed at the same time.

14. The method as claimed in claim 13, wherein forming the first conductive member and forming the second conductive member at the same time comprises:
filling a conductive ink into the first through hole and the second through hole; and
curing the conductive ink in the first through hole and the second through hole.

15. The method as claimed in claim 13, wherein before forming the first conductive member and forming the second conductive member at the same time, the method further comprises:
forming a conductive line in the third dielectric layer.

16. The method as claimed in claim 15, wherein forming the conducive line comprises:
filling a conductive ink into a recess of the third dielectric layer; and
curing the conductive ink in the recess.

17. The method as claimed in claim 15, wherein the first conductive member, the second conductive member and the conductive line are formed integrally.

18. The method as claimed in claim 10, wherein the first base material, the second base material and the third base material are all dies.

19. The method as claimed in claim 1, wherein connecting the second substrate to the first substrate comprises:
coating an adhesive layer onto the first dielectric layer; and
adhering the second dielectric layer of the second substrate to the first dielectric layer of the first substrate using the adhesive layer.

20. A packing structure, comprising:
a first substrate, a second substrate, and a third substrate,
wherein the first substrate comprises a first base material and a first dielectric layer on the first base material,
wherein the second substrate comprises a second base material and a second dielectric layer on the second base material,
wherein the third substrate comprises a third base material and a third dielectric layer on the third base material;
a conductive member directly contacting and surrounded by the first dielectric layer, the second dielectric layer, the second base material, the third dielectric layer, and the third base material,
wherein the conductive member penetrates the third base material and is exposed; and
a conductive line surrounded by the third dielectric layer,
wherein the conductive line is spaced apart from the third base material by the third dielectric layer.
